(19) United States
(12) Patent Application Publication
(10) Pub. No.: US 2026/0271294 A1
(43) Pub. Date: Sep. 10, 2026

(54) SEMICONDUCTOR STRUCTURE

(71) Applicant: MACRONIX INTERNATIONAL CO., LTD., Hsinchu (TW)

(72) Inventor: Li-Yen LIANG, Kaohsiung City (TW)

(21) Appl. No.: 19/074,557

(22) Filed: Mar. 10, 2025

(51) Int. Cl. H10B 43/35; H10B 43/10; H10B 43/27

(52) U.S. Cl. CPC H10B 43/35; H10B 43/27; H10B 43/10

(57) ABSTRACT

A semiconductor structure is provided. The semiconductor structure includes a substrate, an insulating stacked structure on the substrate, a stacked structure on the substrate and including conductive layers and first insulating layers stacked alternately, a pillar element penetrating the stacked structure and including a memory layer and a channel layer, a first resistor element, and a dielectric film covering an upper surface of the first resistor element. The memory layer surrounds the channel layer. A portion of the first resistor element is in the insulating stacked structure. Another portion of the first resistor element is above the insulating stacked structure. The semiconductor structure has a device region and a peripheral region. The insulating stacked structure and the first resistor element are in the peripheral region. The stacked structure is in the device region.

### BACKGROUND

### Technical Field

The disclosure relates to a semiconductor structure, and more particularly to a semiconductor structure including a resistor element.

### Description of the Related Art

3-dimensional (3D) semiconductor structures have been developed for a long time since 2-dimensional semiconductor structures reached scaling limitations and did not meet market demand. However, the development of 3D semiconductor structures faces huge challenges, such as difficulty in manufacturing process integration, complicated device design, difficulty in accurately controlling profiles of components, and electrical performance of semiconductor structures. In order to solve these problems, the development of new 3D semiconductor structures becomes increasingly important.

It is desirable to provide technology for a semiconductor structure with an improved layout.

### SUMMARY

The disclosure provides a semiconductor structure including a resistor element with uniform thickness, which can improve the electrical performance of the semiconductor structure.

According to embodiments of the present disclosure, a semiconductor structure is provided. The semiconductor device includes a substrate, an insulating stacked structure on the substrate, a stacked structure on the substrate and including conductive layers and first insulating layers stacked alternately, a pillar element penetrating the stacked structure and including a memory layer and a channel layer, a first resistor element, and a dielectric film covering an upper surface of the first resistor element. A portion of the first resistor element is in the insulating stacked structure. Another portion of the first resistor element is above the insulating stacked structure. The semiconductor structure has a device region and a peripheral region. The insulating stacked structure and the first resistor element are in the peripheral region. The stacked structure is in the device region.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a layout of a semiconductor structure according to some embodiments of the present disclosure.

FIG. 2A illustrates a schematic cross-sectional view of a semiconductor structure according to some embodiments of the present disclosure.

FIG. 2B illustrates a schematic cross-sectional view of a semiconductor structure according to some embodiments of the present disclosure.

FIG. 3A shows a circuit diagram of the semiconductor structure of FIG. 1.

FIG. 3B illustrates a three-dimensional schematic view of a pillar element of the semiconductor structure of FIG. 1.

FIG. 3C illustrates a schematic top view of a pillar element of the semiconductor structure of FIG. 1.

FIG. 4A illustrates a three-dimensional schematic view of a pillar element according to another embodiment of the present disclosure.

FIG. 4B shows a circuit diagram of a semiconductor structure according to some embodiments of the present disclosure.

FIG. 5 to FIG. 12 illustrate schematic cross-sectional views of structures at various stages of a method for manufacturing a semiconductor structure according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material. As used in the specification and the appended claims, term “etching” includes, but are not limited to, dry etching and wet etching. As used in the specification and the appended claims, term “polishing process” includes, but is not limited to, a chemical-mechanical planarization (CMP) and an ion milling process. The terms “etching” and “polishing process” used in the specification and the appended claims may replace with each other, and a person of ordinary skill in the art can select an appropriate removal technology depending on the structure and material.

Embodiments according to the present disclosure can be applied to many different types of three-dimensional semiconductor structures. The semiconductor structure may include a memory device, such as a three-dimensional non-volatile memory device. For example, the three-dimensional non-volatile memory device can be a three-dimensional NOR type flash memory device, a three-dimensional NAND type flash memory device or any type of memory devices.

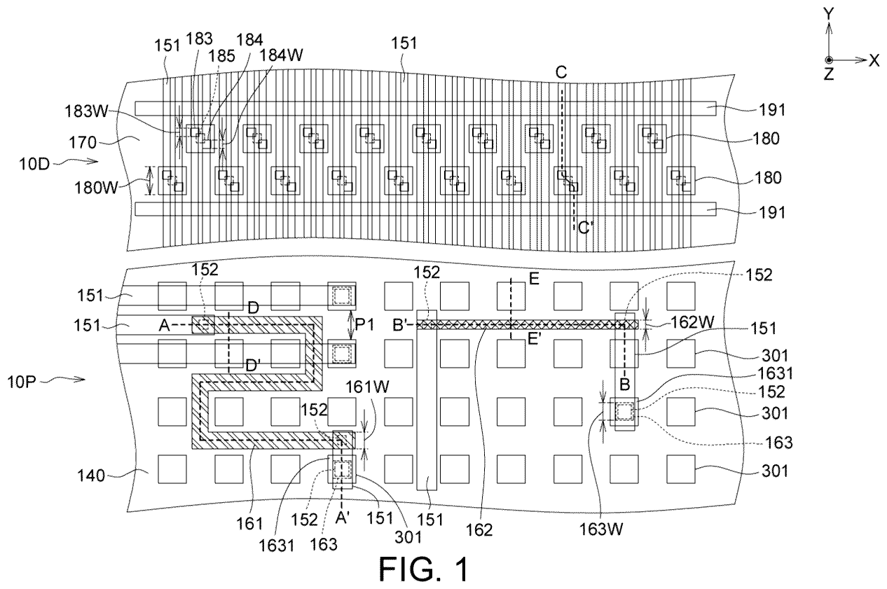

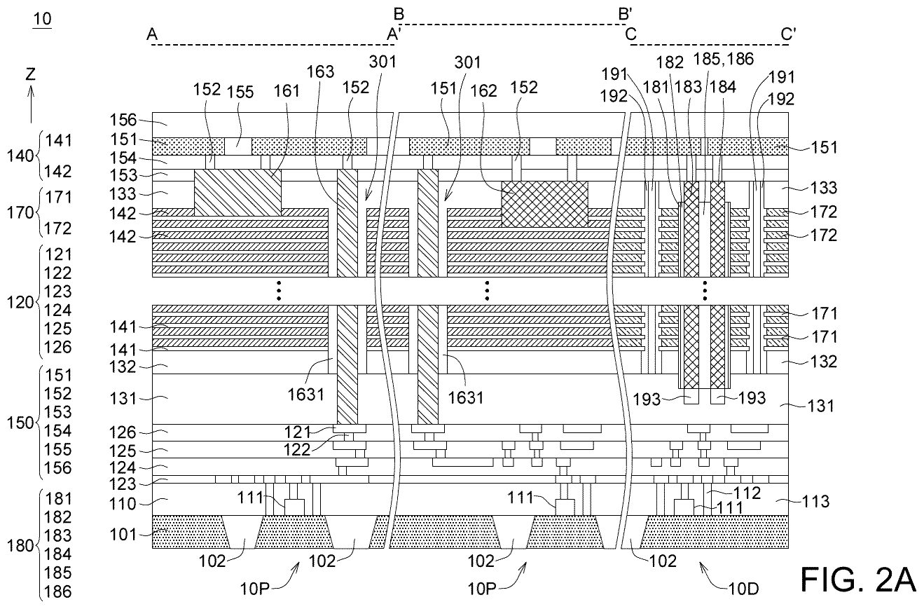

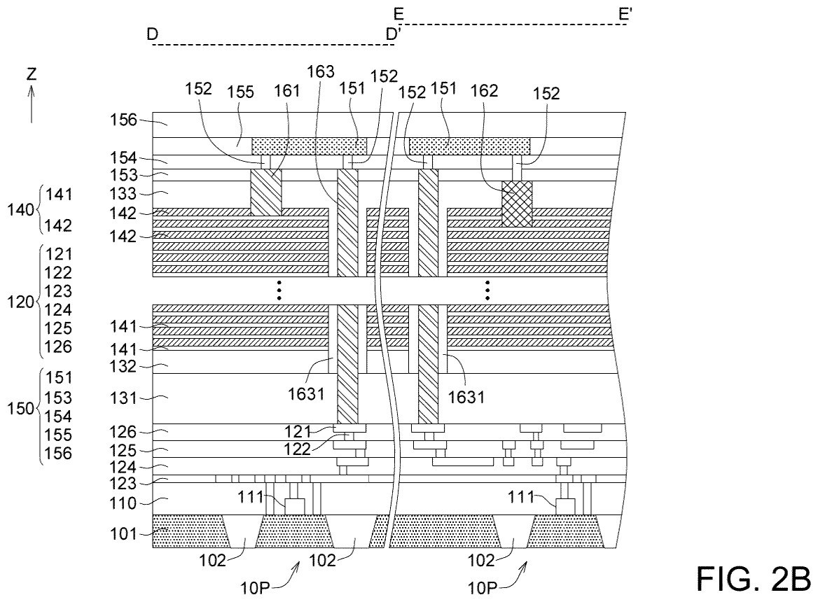

Referring to FIGS. 1, 2A and 2B, FIG. 1 illustrates a layout of a semiconductor structure 10 according to some embodiments of the present disclosure, FIG. 2A illustrates a schematic cross-sectional view of the semiconductor structure 10 according to some embodiments of the present disclosure, FIG. 2B illustrates a schematic cross-sectional view of the semiconductor structure 10 according to some embodiments of the present disclosure. FIG. 2A shows three portions of the semiconductor structure 10, illustrated along the lines AA′, BB′ and CC′ in FIG. 1. FIG. 2B shows three portions of the semiconductor structure 10, illustrated along the lines DD′ and EE′ in FIG. 1. The semiconductor structure 10 includes a substrate 101, an insulating stacked structure 140 on the substrate 101, a stacked structure 170 on the substrate 101, a pillar element 180 penetrating the stacked structure 170, a first resistor element 161, and a dielectric film (such as an interlayer dielectric film 154) covering an upper surface of the first resistor element 161. A portion of the first resistor element 161 is in the insulating stacked structure 140, and another portion of the first resistor element 161 is above the insulating stacked structure 140.

The semiconductor structure 10 has a device region 10D and a peripheral region 10P. The peripheral region 10P may be disposed near the device region 10D. The peripheral region 10P may be adjacent to the device region 10D. The peripheral region 10P may surround the device region 10D. The configuration of the device region 10D can depend on the type of semiconductor structure 10. For example, when the semiconductor structure 10 includes a memory device, the semiconductor structure 10 may include memory cells in the device region 10D. The present embodiment uses NOR type memory cells as an example to illustrate one possible configuration of the device region 10D, but the present disclosure is not limited thereto.

The substrate 10 extends along a lateral direction and across the device region 10D and the peripheral region 10P. For example, the lateral direction can be X direction and/or Y direction. The insulating stacked structure 140 may be disposed on the substrate 101 along a longitudinal direction. For example, the longitudinal direction can be Z direction. The longitudinal direction may be parallel to the normal direction of the upper surface of the substrate 101. The lateral direction is perpendicular to the longitudinal direction. The insulating stacked structure 140 and the first resistor element 161 are in the peripheral region 10P. The insulating stacked structure 140 includes insulating layers 141 (second insulating layer) and insulating films 142 stacked alternately along the longitudinal direction The insulating layers 141 and the insulating films 142 can include different materials. The insulating films 142 are separated from each by the insulating layers 141. The insulating layers 141 are separated from each other by the insulating films 142. The insulating layers 141 and the insulating films 142 may extend along the lateral direction. In the present embodiment, the lowermost layer in the insulating stacked structure 140 (i.e. the layer closest to the substrate 101 among the insulating stacked structure 140) is the insulating layer 141, and the uppermost layer in the insulating stacked structure 140 (i.e. the layer farthest from the substrate 101 among the insulating stacked structure 140) is the insulating film 142, but the present disclosure is not limited thereto. The uppermost insulating film 142 among the insulating films 142 can be understood as the first insulating film; the insulating film 142 adjacent to the first insulating film and located below the first insulating film among the insulating films 142 can be understood as the second insulating film; the insulating film 142 adjacent to the second insulating film and located below the second insulating film among the insulating films 142 can be understood as the third insulating film; the insulating film 142 adjacent to the third insulating film and located below the third insulating film among the insulating films 142 can be understood as the fourth insulating film, other insulating films 142 can also be deduced in the same way. The first insulating film, the second insulating film, the third insulating film and the fourth insulating film are arranged sequentially from top to bottom. In the present embodiment, the first insulating film is located on top of the insulating stacked structure 140.

The first resistor element 161 may not be completely buried in the insulating stacked structure 140. An upper surface of the first resistor element 161 can be higher than an upper surface of the first insulating film of the insulating stacked structure 140 in the longitudinal direction. The first resistor element 161 can overlap N insulating films 142 of the insulating films 142 in the lateral direction, and 1≤N≤3. In an embodiment, 1≤N≤2. In an embodiment, N=1. When N=1, the first resistor element 161 can overlap the first insulating film of the insulating films 142 in the lateral direction. When N=2, the first resistor element 161 can overlap the first insulating film and the second insulating film of the insulating films 142 in the lateral direction. When N=3, the first resistor element 161 can overlap the first insulating film, the second insulating film and the third insulating film of the insulating films 142 in the lateral direction. A lower surface of the first resistor element 161 can be higher than an upper surface of the fourth insulating film or an upper surface of the third insulating film or an upper surface of the second insulating film in the longitudinal direction. In an embodiment, the lower surface of the first resistor element 161 can be in the first insulating film (i.e. the lower surface of the first resistor element 161 can be covered by the first insulating film). In an embodiment, the lower surface of the first resistor element 161 may be at the same height as the lower surface of the first insulating film (as show in FIG. 2A). In an embodiment, the lower surface of the first resistor element 161 can be in the second insulating film (i.e. the lower surface of the first resistor element 161 can be covered by the second insulating film). In an embodiment, the lower surface of the first resistor element 161 may be at the same height as the lower surface of the second insulating film.

The stacked structure 170 may be disposed on the substrate 101 along the longitudinal direction. The stacked structure 170 is in the device region 10D. The stacked structure 170 may be adjacent to the insulating stacked structure 170. The stacked structure 170 and the insulating stacked structure 140 are disposed in a non-overlap manner in the longitudinal direction. The stacked structure 170 includes conductive layers 172 and insulating layers 171 (first insulating layer) stacked alternately along the longitudinal direction. The insulating layers 171 are separated from each other by the conductive layers 172. The conductive layers 172 are separated from each other and electrically isolated from each other by the insulating layers 171. The insulating layers 171 and the conductive layers 172 may extend along the lateral direction. In the present embodiment, the lowermost layer in the stacked structure 170 (i.e. the layer closest to the substrate 101 among the stacked structure 170) is the insulating layer 171, and the uppermost layer in the stacked structure 170 (i.e. the layer farthest from the substrate 101 among the stacked structure 170) is the conductive layer 172, but the present disclosure is not limited thereto. In an embodiment, the insulating layers 141 of the insulating stacked structure 140 and the insulating layers 171 of the stacked structure 170 can have a one-to-one correspondence, that is, one insulating layer 141 and one insulating layer 171 that corresponds to this insulating layer 141 can have the same height (or level) in the longitudinal direction. In an embodiment, the insulating films 142 of the insulating stacked structure 140 and the conductive layers 172 of the stacked structure 170 can have a one-to-one correspondence, that is, one insulating film 142 and one conductive layer 172 that corresponds to this insulating film 142 can have the same height (or level) in the longitudinal direction.

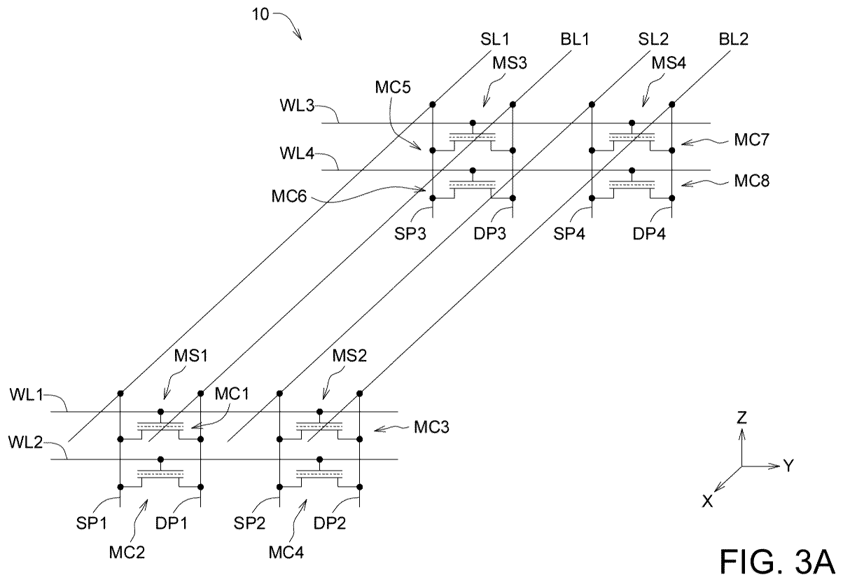

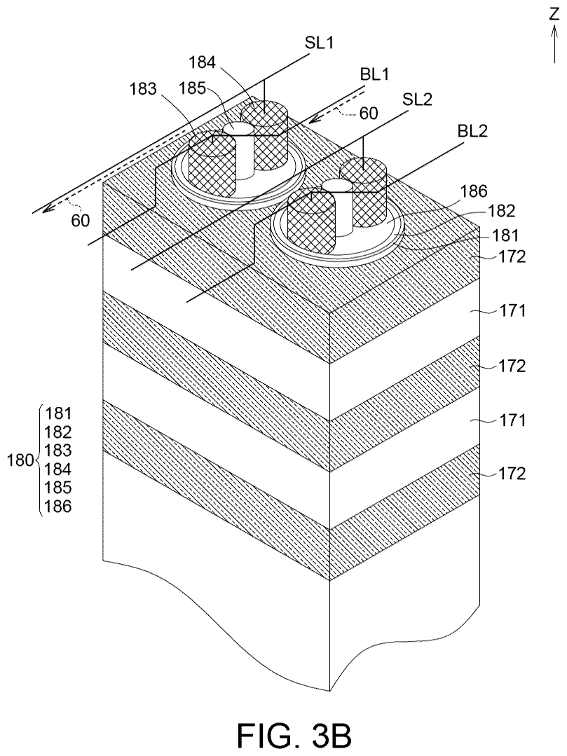

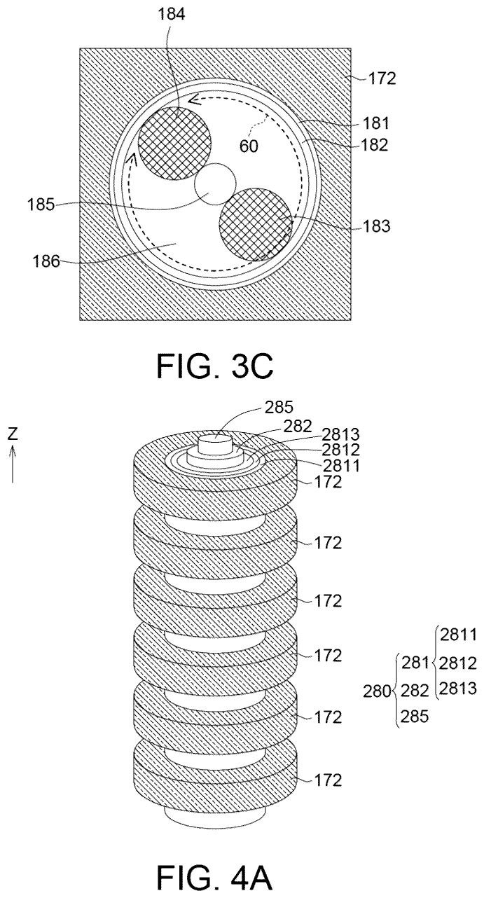

The semiconductor structure 10 may include one or more pillar elements 180. The pillar elements 180 can be separated from each other. The pillar elements 180 can extend along the longitudinal direction and penetrate the stacked structure 170. The pillar elements 180 are in the device region 10D. The pillar element 180 includes a memory layer 181, a channel layer 182, a first conductive pillar 183, a second conductive pillar 184 and an insulating pillar 185. The insulating pillar 185 is disposed between the first conductive pillar 183 and the second conductive pillar 184. The first conductive pillar 183 is electrically isolated from the second conductive pillar 184 by the insulating pillar 185. The first conductive pillar 183 can be functioned as a drain structure. The second conductive pillar 184 can be functioned as a source structure. The conductive layer 172 can be functioned as a gate structure. The first conductive pillar 183, the second conductive pillar 184 and the insulating pillar 185 may extend along a direction perpendicular to the conductive layer 172. The channel layer 182 may have a tubular shape and enclose the first conductive pillar 183, the second conductive pillar 184 and the insulating pillar 185. The channel layer 182 can be electrically connected to the first conductive pillar 183 and the second conductive pillar 184. The memory layer 181 may have a tubular shape and enclose the channel layer 182. In an embodiment, the pillar element 180 can further include a dielectric filler (e.g. a dielectric filler 186 shown in FIG. 3A) which may be disposed between the channel layer 182 and the first conductive pillar 183, and/or between the channel layer 182 and the second conductive pillar 184, and/or between the channel layer 182 and the insulating pillar 185. The channel layer 182 may be disposed between the dielectric filler and the memory layer 181. A width 180W of the pillar element 180 can be equal to or substantially equal to a width of the memory layer 181.

The semiconductor structure 10 can further include a second resistor element 162. The second resistor element 162 is in the peripheral region 10P. A portion of the second resistor element 162 is in the insulating stacked structure 140, and another portion of the second resistor element 162 is above the insulating stacked structure 140. The first resistor element 161 and the second resistor element 162 may include the same or different materials. The second resistor element 162 may not be completely buried in the insulating stacked structure 140. An upper surface of the second resistor element 162 can be higher than an upper surface of the first insulating film of the insulating stacked structure 140 in the longitudinal direction. The second resistor element 162 can overlap M insulating films 142 of the insulating films 142 in the lateral direction, and 1≤M≤3. In an embodiment, 2≤M≤3. When M=1, the second resistor element 162 can overlap the first insulating film of the insulating films 142 in the lateral direction. When M=2, the second resistor element 162 can overlap the first insulating film and the second insulating film of the insulating films 142 in the lateral direction. When M=3, the second resistor element 162 can overlap the first insulating film, the second insulating film and the third insulating film of the insulating films 142 in the lateral direction. A lower surface of the second resistor element 162 can be higher than an upper surface of the fourth insulating film or an upper surface of the third insulating film or an upper surface of the second insulating film in the longitudinal direction. In an embodiment, the lower surface of the second resistor element 162 can be in the second insulating film (i.e. the lower surface of the second resistor element 162 can be covered by the second insulating film). In an embodiment, the lower surface of the second resistor element 162 may be at the same height as the lower surface of the second insulating film (as show in FIG. 2A). In an embodiment, the lower surface of the second resistor element 162 can be in the third insulating film (i.e. the lower surface of the second resistor element 162 can be covered by the third insulating film). In an embodiment, the lower surface of the second resistor element 162 may be at the same height as the lower surface of the third insulating film. In FIG. 2A and FIG. 2B, the lower surface of the first resistor element 161 and the lower surface of the second resistor element 162 are at different levels of the insulating stacked structure 140 and at different heights, but the present disclosure is not limited thereto.

The semiconductor structure 10 can further include an isolation structure 102, a device layer 110, a lower interconnection structure 120, a dielectric layer 131, a semiconductor layer 132, a dielectric film 133, an upper interconnection structure 150, a contact element 163, a protection layer 1631, a separation element 191, a separation film 192 and a stop layer 193. The semiconductor structure 10 may include one or more isolation structures 102. The isolation structure 102 may be formed in the substrate 101. The isolation structure 102 may be in the device region 10D and/or the peripheral region 10P. The device layer 110 may be disposed on the substrate 101 along the longitudinal direction. The device layer 110 may be between the substrate 101 and the insulating stacked structure 140. The device layer 110 may be between the substrate 101 and the stacked structure 170. The device layer 110 may extend along the lateral direction and across the device region 10D and the peripheral region 10P. The device layer 110 may include one or more transistors 111, one or more coupling elements 112 and a dielectric material layer 113. The drawings show that the transistor 111 is on the upper surface of the substrate 101, but the present disclosure is not limited thereto. The transistor 111 can be disposed near the upper surface of the substrate 101, that is, the transistor 111 may be completely disposed above the upper surface of the substrate 101; or alternatively, a portion of the transistor 111 (e.g. the gate structure) may be disposed above the upper surface of the substrate 101, and another portion of the transistor 111 (e.g. the drain structure and/or source structure) may be disposed under the upper surface of the substrate 101 and in the substrate 101; or alternatively, the transistor 111 may be completely disposed in the substrate 101. The dielectric material layer 113 may be disposed on the substrate 101 along the longitudinal direction. The transistor 111 may be a N-type metal-oxide-semiconductor field-effect transistor (NMOS), a P-type metal-oxide-semiconductor field-effect transistor (PMOS), or a complementary metal-oxide-semiconductor circuit (CMOS). The coupling elements 112 may be disposed in the dielectric material layer 113. The transistors 111 may be electrically connected to the coupling elements 112. In addition to the transistor 111, the device layer 110 may further include other active devices and/or passive devices (not shown). For example, the active device can be a transistor or a silicon controlled rectifier. For example, the passive device can be a resistor, a capacitor, or an inductor. The isolation structure 102 can be used to separate transistors 111 so that different bias voltages can be applied to well regions of the transistors 111.

The lower interconnection structure 120 may be disposed on the substrate 101 along the longitudinal direction. The lower interconnection structure 120 may be between the device layer 110 and the insulating stacked structure 140. The lower interconnection structure 120 may be between the device layer 110 and the stacked structure 170. The lower interconnection structure 120 may extend along the lateral direction and across the device region 10D and the peripheral region 10P. The lower interconnection structure 120 may include conductive elements 121, conductive via elements 122 and interlayer dielectric layers 123~126. The conductive elements 121 and the conductive via elements 122 may be disposed in the interlayer dielectric layers 123~126. The interlayer dielectric layers 123~126 may be arranged sequentially from bottom to top along the longitudinal direction. The interlayer dielectric layer 123 may be between the interlayer dielectric layer 124 and the dielectric material layer 113. The interlayer dielectric layer 126 may be between the interlayer dielectric layer 125 and the dielectric layer 131. The conductive elements 121 may be electrically connected to the conductive via elements 122. The conductive elements 121 and the conductive via elements 122 may form one or more conductive paths. The conductive elements 121 and the conductive via elements 122 may be electrically connected to the transistors 111 and the coupling elements 112 of the device layer 110. The dielectric layer 131 may be disposed on the substrate 101 along the longitudinal direction. The dielectric layer 131 may be between the lower interconnection structure 120 and the insulating stacked structure 140. The dielectric layer 131 may be between the lower interconnection structure 120 and the stacked structure 170. The dielectric layer 131 may be between the lower interconnection structure 120 and the semiconductor layer 132. The dielectric layer 131 may extend along the lateral direction and across the device region 10D and the peripheral region 10P. The dielectric layer 131 may contact the interlayer dielectric layer 126 of the lower interconnection structure 120. The semiconductor layer 132 may be disposed on the substrate 101 along the longitudinal direction. The semiconductor layer 132 may be between the dielectric layer 131 and the insulating stacked structure 140. The semiconductor layer 132 may contact the dielectric layer 131. The semiconductor layer 132 may contact the lowermost insulating layer 141 in the insulating stacked structure 140. The semiconductor layer 132 may extend along the lateral direction and across the device region 10D and the peripheral region 10P.

The semiconductor structure 10 may include one or more contact elements 163. The contact elements 163 can be separated from each other. The contact elements 163 can extend along the longitudinal direction and penetrate the dielectric layer 131, the semiconductor layer 132, the insulating stacked structure 140 and the dielectric film 133. The contact elements 163 are in the peripheral region 10P. The contact element 163 can be electrically connected to the transistor 111 of the device layer 110 through the conductive element 121 of the lower interconnection structure 120, the conductive via element 122 of the lower interconnection structure 120 and the coupling element 112 of the device layer 110. As shown in FIG. 1, the first resistor element 161 and the second resistor element 162 can be disposed between the contact elements 163. The first resistor element 161 and the second resistor element 162 may not contact the contact elements 163. As shown in FIG. 1, the first resistor element 161, the second resistor element 162 and the contact elements 163 are disposed in a non-overlap manner in the longitudinal direction. The first resistor element 161 can be disposed on one side of the contact element 163. The second resistor element 162 can be disposed on one side of the contact element 163. As shown in FIG. 1, the first resistor element 161, the second resistor element 162 and the holes 301 can be disposed in a non-overlap manner in the longitudinal direction; or, the first resistor element 161, the second resistor element 162 and the holes 301 (or the contact elements 163) are disposed in a non-overlap manner in the plan view. The first resistor element 161 and the second resistor element 162 can be disposed between the holes 301 (or the contact elements 163). As shown in FIG. 1, the first resistor element 161 and the second resistor element 162 can have any length on a plane formed by X direction and Y direction (can be understood as a transverse plane). For example, the lengths of the first resistor element 161 and the second resistor element 162 on the transverse plane can be adjusted according to the required resistance value. For example, the first resistor element 161 and the second resistor element 162 can extend through the contact elements 163 (or extend beyond the contact elements 163) along the lateral direction so that the resistor elements with various resistance values can be formed in the spaces between the contact elements 163. The first resistor element 161 can overlap contact elements 163 in the lateral direction. The second resistor element 162 can overlap contact elements 163 in the lateral direction. The cross-sections of the first resistor element 161 and the second resistor element 162 on the transverse plane may have any shape. For example, the cross-sections of the first resistor element 161 and the second resistor element 162 on the transverse plane can be square, rectangular, S-shaped, U-shaped or serpentine. The shapes of the first resistor element 161 and the second resistor element 162 can be changed according to the arrangement pattern of the holes 301. For example, the cross-sections of the first resistor element 161 and the second resistor element 162 on the transverse plane can be adjusted according to the required resistance value. In an embodiment, a resistance value of the first resistive element 161 is greater than a resistance value of the second resistive element 162.

The semiconductor structure 10 may include one or more protection layers 1631. The protection layer 1631 is on a sidewall of the contact element 163. The protection layer 1631 may surround the contact element 163. The protection layer 1631 can extend along the longitudinal direction and penetrate the semiconductor layer 132 and the insulating stacked structure 140. The protection layers 1631 are in the peripheral region 10P. The contact element 163 may be separated from the insulating stacked structure 140 by the protection layer 1631. The protection layer 1631 and the contact element 163 can be disposed in a hole 301. As shown in FIG. 1, one or more holes 301 can be separated from each other in the peripheral region 10P. As shown in FIG. 1, at least one contact element 163 of the contact elements 163 is between the first resistor element 161 and the stacked structure 170; at least one contact element 163 of the contact elements 163 is between the second resistor element 162 and the stacked structure 170.

The semiconductor structure 10 may include memory cells in the device region 10D and the stacked structure 170. The memory cells can be defined at the intersections of the conductive layers 172 and the channel layers 182 of the pillar elements 180. The pillar element 180 can be understood as a active pillar element.

The semiconductor structure 10 may include one or more separation elements 191 and one or more separation films 192. The separation elements 191 and the separation films 192 can extend along the longitudinal direction and penetrate the semiconductor layer 132, the stacked structure 170 and the dielectric film 133. The separation film 192 is on the sidewall of the separation element 191. The separation element 191 can be separated from the conductive layers 172 by the separation film 192. As shown in FIG. 1, the separation elements 191 and the separation films 192 can extend along the lateral direction (such as X direction). The separation elements 191 and the separation films 192 can be disposed between the pillar elements 180. The separation element 191 can be between the pillar element 180 and the insulating stacked structure 140. The separation elements 191 and the separation films 192 are in the device region 10D. The semiconductor structure 10 may include one or more stop layers 193. The stop layers 193 may be disposed below the stacked structure 170. The stop layers 193 may be disposed in the dielectric layer 131. The stop layers 193 can be used to control or determine the lengths of the first conductive pillar 183 and the second conductive pillar 184. The stop layers 193 are in the device region 10D. In other embodiments, the stop layers 193 can be disposed in the device region 10D and the peripheral region 10P.

The dielectric film 133 may be disposed above the insulating stacked structure 140 and the stacked structure 170 along the longitudinal direction. The dielectric film 133 may be between the insulating stacked structure 140 and the upper interconnection structure 150. The dielectric film 133 may be between the stacked structure 170 and the upper interconnection structure 150. The dielectric film 133 may extend along the lateral direction and across the device region 10D and the peripheral region 10P. The dielectric film 133 may contact the uppermost insulating film 142 of the insulating stacked structure 140. The dielectric film 133 may contact the uppermost conductive layer 172 of the stacked structure 170. The first resistor element 161 and the second resistor element 162 can penetrate the dielectric film 133. The upper surface of the second resistor element 162 may be coplanar with the upper surface of the dielectric film 133. The upper surface of the pillar element 180, the upper surface of the separation element 191 and the upper surface of the separation film 192 may be coplanar with the upper surface of the dielectric film 133. The pillar element 180 can extend along the longitudinal direction and penetrate the dielectric layer 131, the semiconductor layer 132 and the dielectric film 133.

The upper interconnection structure 150 may be disposed above the insulating stacked structure 140 and the stacked structure 170 along the longitudinal direction. The upper interconnection structure 150 may be disposed on the dielectric film 133 along the longitudinal direction. The upper interconnection structure 150 extend along the lateral direction and across the device region 10D and the peripheral region 10P. The upper interconnection structure 150 may include upper conductive elements 151, upper conductive via elements 152 and interlayer dielectric films 153~156. The upper conductive elements 151 and the upper conductive via elements 152 may be disposed in the interlayer dielectric films 153~156. The interlayer dielectric films 153~156 may be arranged sequentially from bottom to top along the longitudinal direction. The interlayer dielectric film 153 may be between the interlayer dielectric film 154 and the dielectric film 133. The interlayer dielectric film 156 may cover the upper surfaces of the upper conductive elements 151. The lengths of the upper conductive via elements 152 in the longitudinal direction may be different. A portion of the upper conductive via elements 152 may be disposed between the upper conductive element 151 and the first resistor element 161, a portion of the upper conductive via elements 152 may be disposed between the upper conductive element 151 and the contact element 163, a portion of the upper conductive via elements 152 may be disposed between the upper conductive element 151 and the second resistor element 162, a portion of the upper conductive via elements 152 may be disposed between the upper conductive element 151 and the pillar element 180. The upper conductive elements 151 may be electrically connected to the upper conductive via elements 152. The upper conductive elements 151 and the upper conductive via elements 152 may form one or more conductive paths. The first resistor element 161 can be electrically connected to the transistor 111 through the upper conductive via element 152 of the upper interconnection structure 150, the upper conductive element 151 of the upper interconnection structure 150, the contact element 163, the conductive element 121 of the lower interconnection structure 120, the conductive via element 122 of the lower interconnection structure 120, and the coupling element 112. The second resistor element 162 can be electrically connected to the transistor 111 through the upper conductive via element 152 of the upper interconnection structure 150, the upper conductive element 151 of the upper interconnection structure 150, the contact element 163, the conductive element 121 of the lower interconnection structure 120, the conductive via element 122 of the lower interconnection structure 120, and the coupling element 112. The first resistor element 161 can penetrate the interlayer dielectric film 153. The interlayer dielectric films 154~156 can be disposed above the first resistor element 161 in the longitudinal direction. The interlayer dielectric film 154 may cover (and/or contact) the upper surface of the first resistor element 161. The interlayer dielectric films 153~156 can be disposed above the second resistor element 162 in the longitudinal direction. The interlayer dielectric film 153 may cover (and/or contact) the upper surface of the second resistor element 162.

As shown in FIG. 1, a pitch P1 between two adjacent holes 301 of the holes 301 is larger than a width 161W of the first resistor element 161, and the pitch P1 and the width 161W are in the lateral direction (e.g. Y direction). The pitch P1 between two adjacent holes 301 of the holes 301 is larger than a width 162W of the second resistor element 162, and the pitch P1 and the width 162W are in the lateral direction (e.g. Y direction). The width 161W of the first resistor element 161 is smaller than or equal to a width 163W of the contact element 163, and the width 161W and the width 163W are in the lateral direction (e.g. Y direction). The width 162W of the second resistor element 162 is smaller than or equal to a width 183W of the first conductive pillar 183, the width 162W of the second resistor element 162 is smaller than or equal to a width 184W of the second conductive pillar 184, and the width 162W, the width 183W and the width 184W are in the lateral direction (e.g. Y direction). The width 183W of the first conductive pillar 183 may be equal to or substantially equal to the width 184W of the second conductive pillar 184.

Referring to FIGS. 3A to 3C, FIG. 3A shows a circuit diagram of the semiconductor structure 10 of FIG. 1, FIG. 3B illustrates a three-dimensional schematic view of a pillar element 180 of the semiconductor structure 10 of FIGS. 1 and 2A, and FIG. 3C illustrates a schematic top view of a pillar element 180 of the semiconductor structure 10 of FIGS. 1 and 2A, corresponding to a plane of one of the conductive layers 172. The semiconductor structure 10 can include memory strings extending along the same direction, such as the memory strings MS1, MS2, MS3 and MS4. Each memory string can include memory cells connected in parallel. For example, the memory string MS1 includes a memory cell MC1 and a memory cell MC2 connected in parallel; the memory string MS2 includes a memory cell MC3 and a memory cell MC4 connected in parallel; the memory string MS3 includes a memory cell MC5 and a memory cell MC6 connected in parallel; the memory string MS4 includes a memory cell MC7 and a memory cell MC8 connected in parallel. The memory cells MC1 and MC3 located in the same horizontal row are electrically connected to the word line WL1, that is, the memory cells MC1 and MC3 share the word line WL1. The memory cells MC2 and MC4 located in the same horizontal row are electrically connected to the word line WL2, that is, the memory cells MC2 and MC4 share the word line WL2. The memory cells MC5 and MC7 located in the same horizontal row are electrically connected to the word line WL3, that is, the memory cells MC5 and MC7 share the word line WL3. The memory cells MC6 and MC8 located in the same horizontal row are electrically connected to the word line WL4, that is, the memory cells MC6 and MC8 share the word line WL4. The memory string MS1 is electrically connected between the source pillar SP1 and the drain pillar DP1. The memory string MS2 is electrically connected between the source pillar SP2 and the drain pillar DP2. The memory string MS3 is electrically connected between the source pillar SP3 and the drain pillar DP3. The memory string MS4 is electrically connected between the source pillar SP4 and the drain pillar DP4. The source pillar SP1 is electrically connected to the source line SL1. The drain pillar DP1 is electrically connected to the bit line BL1. The source pillar SP2 is electrically connected to the source line SL2. The drain pillar DP2 is electrically connected to the bit line BL2. The source lines and the bit lines can be arranged alternately. The source lines and the bit lines may extend in the same direction. The memory strings (such as the memory strings MS1, MS2, MS3 and MS4), the source pillars (such as the source pillars SP1, SP2, SP3 and SP4) and the drain pillars (such as the drain pillars DP1, DP2, DP3 and DP4) of the semiconductor structure 10 may extend in the same direction. In an embodiment, the memory strings MS1 and MS2 on the same plane (such as the plane formed by the Y direction and the Z direction) can belong to a first block, the memory strings MS3 and MS4 on the same plane (such as the plane formed by the Y direction and the Z direction) can belong to a second block, and the first block and the second block share the source line SL1, the source line SL2, the bit line BL1 and the bit line BL2. In an embodiment, depending on the manufacturing method used, memory strings can be arranged in a honeycomb pattern or other patterns. FIG. 3A shows eight memory cells MC1 to MC8 as an example, which does not mean that the present disclosure can only be applied to a semiconductor structure including this number of memory cells; the present disclosure can be applied to a semiconductor structure including any number of memory cells, and the electrical connections can be analogized to the manner shown in FIG. 3A.

The conductive layers 172 can be functioned as word lines, such as the word lines WL1~WL4 shown in FIG. 3A. The first conductive pillars 183 can be functioned as drain structures, such as the drain pillars DP1~DP4 shown in FIG. 3A. The second conductive pillars 184 can be functioned as source structures, such as the source pillars SP1~SP4 shown in FIG. 3A. The upper conductive elements 151 can be functioned as source lines (such as the source line SL1 and SL2 shown in FIG. 3A) and bit lines (such as the bit lines BL1 and BL2 shown in FIG. 3A); or alternatively, the source pillar may be electrically connected to the source line through the upper conductive element 151, and the drain pillar may be electrically connected to the bit line through the upper conductive element 151. If a reading, writing or erasing operation is performed to a specific memory cell (such as the memory cell MC1), an operating voltage higher than the threshold voltage of the memory cell MC1 can be applied to the word line WL1 that is electrically connected to the memory cell MC1, so that a portion (channel region) of the channel layer 182 that intersects with the word line WL1 is turned on to allow the current to enter the first conductive pillar 183 (the drain pillar DP1) from the bit line BL1; then, the current flows from the first conductive pillar 183 (the drain pillar DP1) to the source line SL1 through the channel region that is turned on and the second conductive pillar 184 (the source pillar SP1) sequentially, as indicated by the current direction 60 in FIGS. 3B and 3C.

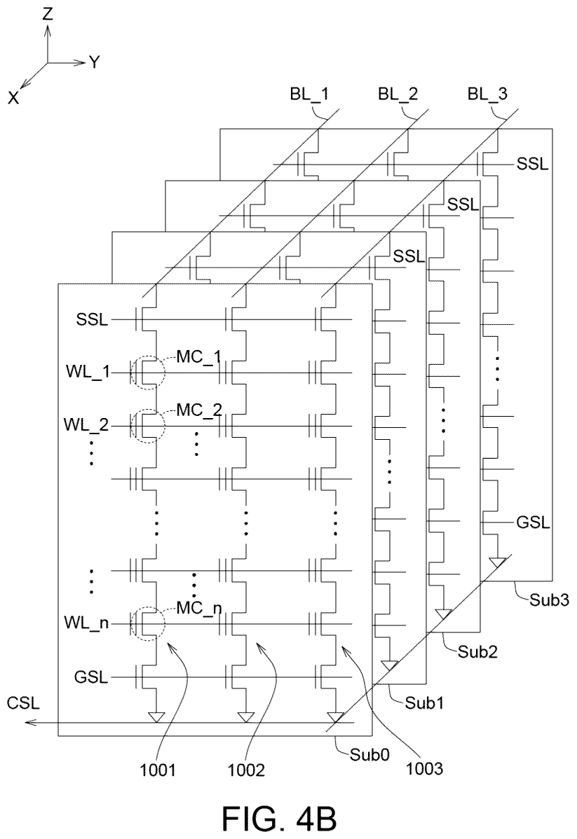

FIG. 4A illustrates a three-dimensional schematic view of a pillar element 280 in the stacked structure 170 according to another embodiment of the present disclosure. The differences between the pillar element 280 shown in FIG. 4A and the pillar element 180 shown in FIGS. 1 to 3C are described below. The pillar element 280 in the device region includes a memory layer 281, a channel layer 282 and an insulating pillar 285. The conductive layer 172 can be functioned as a gate structure. The memory layer 281 may have a tubular shape and enclose the channel layer 282 and the insulating pillar 285. The channel layer 282 may be disposed between the memory layer 281 and the insulating pillar 285. The channel layer 282 may have a tubular shape and enclose the insulating pillar 285. The channel layer 282 may include polycrystalline silicon. The insulating pillar 285 may include oxide. The insulating pillar 285 may extend along a direction perpendicular to the conductive layer 172. The memory layer 281 includes a blocking layer 2811, a charge trapping layer 2812 and a tunneling layer 2813. The blocking layer 2811 may enclose the charge trapping layer 2812 and the tunneling layer 2813. The blocking layer 2811 may be disposed between the conductive layers 172 and the charge trapping layer 2812. The charge trapping layer 2812 may be disposed between the blocking layer 1811 and the tunneling layer 2813. The charge trapping layer 2812 may enclose the tunneling layer 2813. The tunneling layer 2813 may be disposed on an outer surface of the channel layer 282. The blocking layer 2811 may include oxide. The charge trapping layer 2812 may include nitride. The tunneling layer 2813 may include oxide. The memory cells can be defined at the intersections of the conductive layers 172 and the channel layers 282 of the pillar elements 280. In the present embodiment, the memory cells can be NAND type memory cells.

The circuit diagram of the semiconductor structure including the pillar elements 280 is shown in FIG. 4B. The semiconductor structure can include one or more blocks, and each block can include sub-blocks. FIG. 4B show a block in the semiconductor structure, this block can be separated into four sub-blocks Sub0, Sub1, Sub2 and Sub3, and each sub-block can be controlled independently. Each sub-block may include memory strings extending along Z direction and on the same plane (such as a plane formed by Y direction and Z direction), such as memory strings 1001, 1002 and 1003. Each memory string may include memory cells connected in series, such as memory cells MC_1, MC_2 . . . MC_n. The memory cells MC_1, MC_2 . . . MC_n are electrically connected to the word lines WL_1, WL_2 . . . WL_n respectively. The memory cells MC_1 located in the same horizontal row (or can be understood as the memory cells MC_1 located in different memory strings) are electrically connected to the word line WL_1, that is, the memory cells MC_1 share the word line WL_1. The memory cells MC_2 located in the same horizontal row (or can be understood as the memory cells MC_2 located in different memory strings) are electrically connected to the word line WL_2, that is, the memory cells MC_2 share the word line WL_2. The memory cells MC_n located in the same horizontal row (or can be understood as the memory cells MC_n located in different memory strings) are electrically connected to the word line WL_n, that is, the memory cells MC_n share the word line WL_n. The memory string 1001 is electrically connected between a bit line BL_1 and a common source line CSL. The memory string 1001 is electrically connected between a bit line BL_2 and a common source line CSL. The memory string 1003 is electrically connected between a bit line BL_3 and a common source line CSL. The bit lines BL_1, BL_2 and BL_3 may extend along the same direction. The bit lines BL_1, BL_2 and BL_3 may extend along a direction perpendicular to Z direction. A string selection line SSL and the ground selection line GSL are electrically to opposite ends of the memory strings 1001, 1002 and 1003. The string selection line SSL is electrically connected between the memory cell MC_1 of the memory string 1001 and the bit line BL_1. The string selection line SSL is electrically connected between the memory cell MC_1 of the memory string 1002 and the bit line BL_2. The string selection line SSL is electrically connected between the memory cell MC_1 of the memory string 1003 and the bit line BL_3. The ground selection line GSL is electrically connected between the memory cell MC_n of the memory string 1001 and the common source line CSL. The ground selection line GSL is electrically connected between the memory cell MC_n of the memory string 1002 and the common source line CSL. The ground selection line GSL is electrically connected between the memory cell MC_n of the memory string 1003 and the common source line CSL. The string selection lines SSL in different sub-blocks are electrically isolated from each other. The ground selection lines GSL in different sub-blocks are electrically isolated from each other.

In an embodiment, in SLC mode, the memory cells in the same sub-block and electrically connected to the same word line can be defined as a page. In an embodiment, in TLC mode, the memory cells in the same sub-block and electrically connected to the same word line can be defined as three pages including a high page, a middle page and a low page. In an embodiment, the semiconductor structure may further include one or more dummy lines disposed between the string selection line SSL and the memory cell MC_1. In an embodiment, the semiconductor structure may further include one or more dummy lines disposed between the ground selection line GSL and memory cell MC_n. In an embodiment, the semiconductor structure may further include one or more dummy lines disposed between the memory cells, for example, one or more dummy lines may be disposed in the middle of the memory strings 1001, 1002, and 1003. FIG. 4B shows three memory strings as an example, which does not mean that the present disclosure can only be applied to a semiconductor structure including this number of memory strings; the present disclosure can be applied to a semiconductor structure including any number of memory strings, and the electrical connections can be analogized to the manner shown in FIG. 4A.

The topmost conductive layer 170 among the conductive layers 170 can be functioned as the string selection line SSL. The lowermost conductive layer 170 among the conductive layers 170 can be functioned as the ground selection line GSL. The conductive layers 170 between the topmost conductive layer 170 and the lowermost conductive layer 170 can be functioned as the word lines WL_1, WL_2 . . . WL_n. The common source line CSL can be a conductive layer between the lowermost conductive layer 170 and the substrate 101.

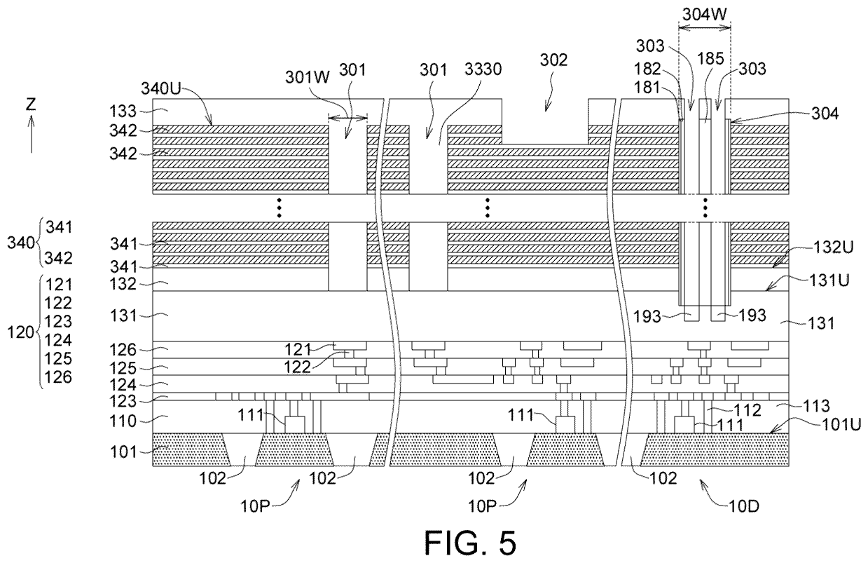

FIG. 5 to FIG. 12 illustrate a method for manufacturing a semiconductor structure according to some embodiments of the present disclosure. The steps illustrated in FIGS. 5 to 12 can be performed sequentially or in other orders, the present disclosure is not limited thereto.

Referring to FIG. 5, FIG. 5 shows a schematic cross-sectional view of the structure at one stage of the method for manufacturing the semiconductor structure. A substrate 101, an isolation structure 102, a device layer 110, a lower interconnection structure 120, a dielectric layer 131, a semiconductor layer 132, a stop layer 193 and an insulating stacked structure 340 are provided. The isolation structure 102 can be formed in the substrate 101. The device layer 110, the lower interconnection structure 120 and the dielectric layer 131 can be formed sequentially above an upper surface 101U of the substrate 101 along a longitudinal direction. For example, the longitudinal direction can be the normal direction of the upper surface 101U of the substrate 101 or Z direction. The configuration shown in FIG. 5 can be a CMOS under array (CuA) configuration, but the present disclosure is not limited to such specific configuration. For example, the present disclosure can also be applied to a CMOS near array (CnA) configuration. The substrate 101, the device layer 110, the lower interconnection structure 120, the dielectric layer 131, the semiconductor layer 132 and the insulating stacked structure 340 can extend along a lateral direction and across a device region 10D and a peripheral region 10P of the semiconductor structure. That is, each of the substrate 101, the device layer 110, the lower interconnection structure 120, the dielectric layer 131, the semiconductor layer 132 and the insulating stacked structure 340 has a portion in the device region 10D and another portion in the peripheral region 10P. The lateral direction is perpendicular to the longitudinal direction. The lateral direction can be perpendicular to the normal direction of the upper surface 101U of the substrate 101. The lateral direction can be parallel to the upper surface 101U of the substrate 101. The stop layer 193 can be formed in the dielectric layer 131. The stop layer 193 can be completely buried in the dielectric layer 131. The semiconductor layer 132 can be formed above the dielectric layer 131. The substrate 132 may include a semiconductor material such as doped or undoped monocrystalline silicon, doped or undoped polycrystalline silicon, or germanium. The isolation structure 102 may include an insulating material such as oxide. The coupling element 112 of the device layer 110, the conductive element 121 of the lower interconnection structure 120, and the conductive via element 122 of the lower interconnection structure 120 may include conductive materials such as tungsten, cobalt, copper, aluminum or silicide. In an embodiment, the coupling element 112, the conductive element 121 and the conductive via element 122 include tungsten. The dielectric material layer 113 of the device layer 110, the interlayer dielectric layers 123~126 of the lower interconnection structure 120, and the dielectric layer 131 may include dielectric materials such as oxide. In an embodiment, the dielectric material layer 113, the interlayer dielectric layers 123~126 and the dielectric layer 131 include silicon oxide. The semiconductor layer 132 may include a semiconductor material such as doped or undoped monocrystalline silicon, doped or undoped polycrystalline silicon, or germanium. In an embodiment, the semiconductor layer 132 includes polycrystalline silicon. The stop layer 193 may include polycrystalline silicon.

The insulating stacked structure 340 can be formed on the semiconductor layer 132. The insulating stacked structure 340 includes insulating layers 341 and insulating films 342 stacked alternately along the longitudinal direction The insulating films 342 are separated from each by the insulating layers 341. The insulating layers 341 are separated from each other by the insulating films 342. The insulating layers 341 and the insulating films 342 may extend along the lateral direction. In the present embodiment, the lowermost layer in the insulating stacked structure 340 (i.e. the layer closest to the substrate 101 among the insulating stacked structure 340) is the insulating layer 341, and the uppermost layer in the insulating stacked structure 340 (i.e. the layer farthest from the substrate 101 among the insulating stacked structure 340) is the insulating film 342, but the present disclosure is not limited thereto.

The insulating layers 341 and the insulating films 342 can include different materials. The insulating layers 341 may include an insulating materials such as oxide. The insulating films 342 may include an insulating materials such as nitride. In an embodiment, the insulating layers 341 include silicon oxide, and the insulating films 342 include silicon nitride. The insulating layers 341 and the insulating films 342 can be formed alternately on an upper surface 132U of the semiconductor layer 132 through a deposition process to form the insulating stacked structure 340.

One or more holes 304 can be formed in the device region 10D. The holes 304 can be separated from each other. The holes 304 can extend along the longitudinal direction and penetrate the insulating stacked structure 340 and the semiconductor layer 132. The bottom of the hole 304 can be in the dielectric layer 131. A sidewall of the dielectric layer 131, a sidewall of the semiconductor layer 132, sidewalls of the insulating layers 341 and sidewalls of the insulating films 342 are exposed by the hole 304. A portion of the insulating stacked structure 340, a portion of the semiconductor layer 132 and a portion of the dielectric layer 131 can be removed through an etching process to form the holes 304 in the insulating stacked structure 340. The etching process for forming the hole 304 can use the semiconductor layer 132 as an etch stop layer; the etching process can stop at the upper surface of the semiconductor layer 132, and then proceed downward through semiconductor layer 132.

Then, a memory layer 181 and a channel layer 182 can be formed sequentially on the a sidewall of the hole 304. The memory layer 181 can be formed on the sidewall of the hole 304 through a deposition process, and then the channel layer 182 can be formed on a sidewall of the memory layer 181 through a deposition. The memory layer 181 may include a multilayer structure known from memory technologies, such as ONO (oxide-nitride-oxide), ONONO (oxide-nitride-oxide-nitride-oxide), ONONONO (oxide-nitride-oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), MA BE-SONOS (metal-high-k bandgap-engineered silicon-oxide-nitride-oxide-silicon), and combinations of those layers. The channel layer 182 may include a semiconductor material, such as doped or undoped monocrystalline silicon, or doped or undoped polycrystalline silicon. In an embodiment, the channel layer 182 includes doped or undoped polycrystalline silicon.

Then, a dielectric material 3330 is formed in the holes 304. A portion of the dielectric material 3330 in the hole 304 (not shown) can be surrounded by the channel layer 182 and can contact the channel layer 182. The dielectric material 3330 can be formed in the holes 304 through a deposition process. The dielectric material 3330 can be oxide. In an embodiment, the dielectric material 3330 is silicon oxide.

Then, an insulating pillar 185 penetrating the dielectric material 3330 can be formed in the hole 304. The insulating pillar 185 can extend along the longitudinal direction. The insulating pillar 185 can be surrounded by the dielectric material 3330. The dielectric material 3330 can be between the insulating pillar 185 and the channel layer 182. A portion of the dielectric material 3330 in the hole 304 can be removed through an etching process to form an opening in the dielectric material 3330, and the insulating pillar 185 can be formed in the opening through a deposition process. The insulating pillar 185 may include an insulating material such as nitride. In an embodiment, the insulating pillar 185 include silicon nitride.

Then, one or more holes 301 can be formed in the peripheral region 10P. The holes 301 can be separated from each other. The holes 301 can extend along the longitudinal direction and penetrate the insulating stacked structure 340 and the semiconductor layer 132. An upper surface 131U of the dielectric layer 131, a sidewall of the semiconductor layer 132, sidewalls of the insulating layers 341 and sidewalls of the insulating films 342 are exposed by the hole 301. A portion of the insulating stacked structure 340 and a portion of the semiconductor layer 132 can be removed through an etching process to form the holes 301 in the insulating stacked structure 340. In an embodiment, a width 301W of the hole 301 in the lateral direction can be equal to or substantially equal to the width 304W of the hole 304 in the lateral direction.

Then, a dielectric material 3330 is formed in the holes 301. A portion of the dielectric material 3330 in the hole 301 may contact the insulating stacked structure 340. The dielectric material 3330 can be formed in the holes 301 through a deposition process.

Then, a dielectric film 133 is formed on an upper surface 340U of the insulating stacked structure 340. The dielectric film 133 can extend along the lateral direction and across the device region 10D and the peripheral region 10P. The dielectric film 133 can cover the upper surface 340U of the insulating stacked structure 340, the portion of the dielectric material 3330 in the hole 301, the portion of the dielectric material 3330 in the hole 304, an upper surface of the memory layer 181, an upper surface of the channel layer 182 and an upper surface of the insulating pillar 185. The dielectric film 133 may include a dielectric material such as oxide. In an embodiment, the dielectric film 133 includes silicon oxide.

Then, two holes 303 are formed in the device region 10D and a hole 302 is formed in the peripheral region 10P. Two holes 303 can be within the hole 304. Two holes 303 are separated from each other by the insulating pillar 185. The holes 303 can be surrounded by the channel layer 182 and the memory layer 181. A sidewall of the dielectric film 133, a sidewall of the dielectric material 3330, a sidewall of the insulating pillar 185, a sidewall of the channel layer 182 and an upper surface of the stop layer 193 are exposed by the hole 303. The hole 302 is in the dielectric film 133 and the insulating stacked structure 340. A portion of the dielectric film 133 and a portion of the dielectric material 3330 can be removed through an etching process to form the holes 303. The retained portion of the dielectric material 3330 in the hole 304 is the dielectric filler (not shown). A portion of the insulating stacked structure 340 and a portion of the dielectric film 133 can be removed through an etching process to form the hole 302. In an embodiment, the hole 302 and the holes 303 can be formed through the same etching process, the etching process for forming the hole 302 and the holes 303 is a selective etching process, and the etching rate of oxide (e.g. silicon oxide) is higher than the etching rate of nitride (e.g. silicon nitride) in this etching process; since the holes 303 is mainly formed by removing oxide (e.g. the dielectric material 3330), and formation of the hole 302 involves removing nitride (e.g. the insulating film 342), the selective etching process for forming the hole 302 will stop at the first to third insulating films 342 from the top in the insulating stacked structure 340. When the selective etching process for forming the hole 302 stops at the first insulating film 342 from the top in the insulating stacked structure 340, the bottom of the hole 302 can be the first insulating film 342, or the bottom of the hole 302 can be the insulating layer 341 below and adjacent to the first insulating film 342 (that is, the etching process removes the first insulating film 342, and shortly afterward, the etching process stops). When the selective etching process for forming the hole 302 stops at the second insulating film 342 from the top in the insulating stacked structure 340, as shown in FIG. 5, the bottom of the hole 302 can be the second insulating film 342, or the bottom of the hole 302 can be the insulating layer 341 below and adjacent to the second insulating film 342 (that is, the etching process removes the second insulating film 342, and shortly afterward, the etching process stops). When the selective etching process for forming the hole 302 stops at the third insulating film 342 from the top in the insulating stacked structure 340, the bottom of the hole 302 can be the third insulating film 342, or the bottom of the hole 302 can be the insulating layer 341 below and adjacent to the third insulating film 342 (that is, the etching process removes the third insulating film 342, and shortly afterward, the etching process stops).

The etching process for forming the hole 303 can use the stop layer 193 as an etch stop layer.

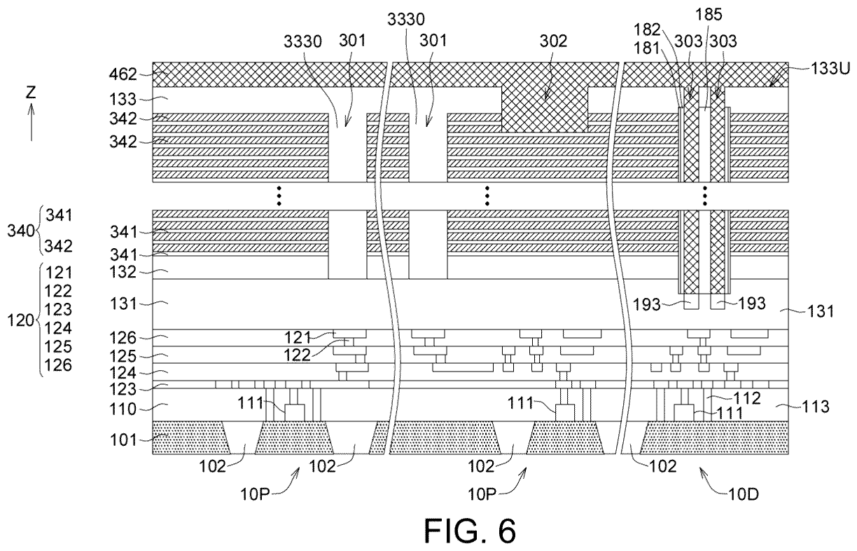

Referring to FIG. 6, FIG. 6 shows a schematic cross-sectional view of the structure at one stage of the method for manufacturing the semiconductor structure. A conductive material 462 is formed. The conductive material 462 can be formed on an upper surface 133U of the dielectric film 133. The conductive material 462 can extend along the lateral direction and across the device region 10D and the peripheral region 10P. The conductive material 462 can be formed in the holes 302 and 303. The conductive material 462 may be a semiconductor material or metal material; for example, the semiconductor material is doped or undoped polycrystalline silicon; for example, metal material is tungsten. In an embodiment, the conductive material 462 is doped or undoped polycrystalline silicon.

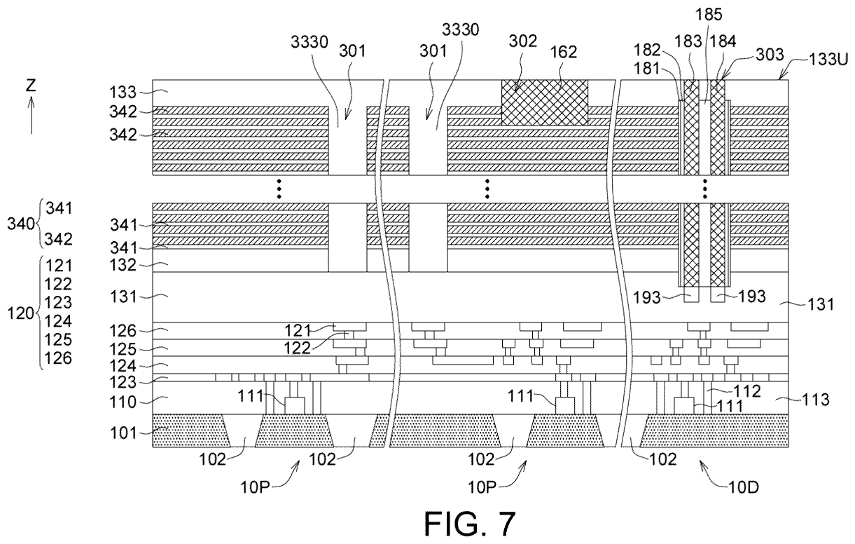

Referring to FIG. 7, FIG. 7 shows a schematic cross-sectional view of the structure at one stage of the method for manufacturing the semiconductor structure. A second resistor element 162 in the peripheral region 10P is formed. A first conductive pillar 183 in the device region 10D and a second conductive pillar 184 in the device region 10D are formed. A portion of the conductive material 462 on the upper surface 133U of the dielectric film 133 can be removed through an etching process, and portions of the conductive material 462 in the holes 302 and 303 are retained. The portion of the conductive material 462 in the hole 302 is the second resistor element 162. The portions of the conductive material 462 in the holes 303 are the first conductive pillar 183 and the second conductive pillar 184. The memory layer 181, the channel layer 182, the first conductive pillar 183, the second conductive pillar 184 and the insulating pillar 185 can form a pillar element 180. Through the selectivity of the etching process and the characteristics of materials, a resistor element with uniform thickness in the longitudinal direction can be formed.

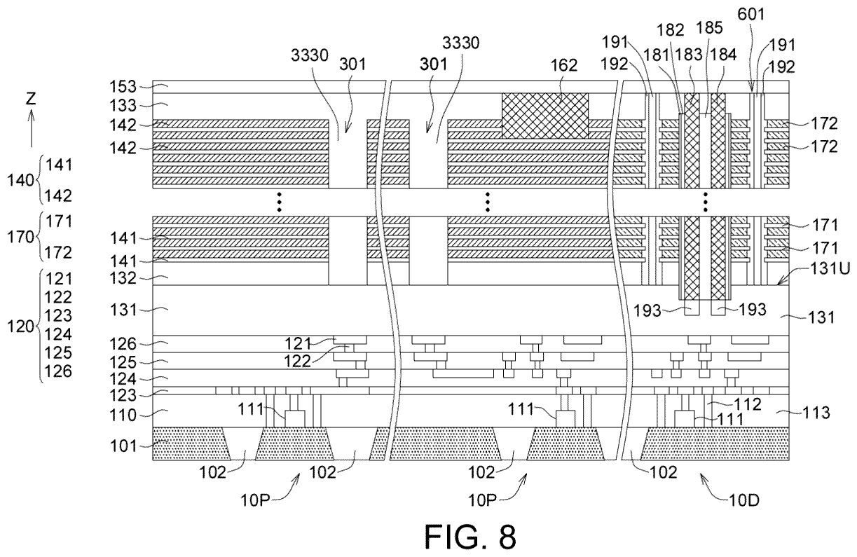

Referring to FIG. 8, FIG. 8 shows a schematic cross-sectional view of the structure at one stage of the method for manufacturing the semiconductor structure. A separation element 191 in the device region 10D, a separation film 192 in the device region 10D, a stacked structure 170 in the device region 10D, an insulating stacked structure 140 in the peripheral region 10P and an interlayer dielectric film 153 across the device region 10D and the peripheral region 10P are formed. The separation element 191 and the separation film 192 can extend along the longitudinal direction and penetrate the stacked structure 170. The interlayer dielectric film 153 is above the stacked structure 170 and the insulating stacked structure 140. The manufacturing steps involved in forming the structure shown in FIG. 8 from the structure shown in FIG. 7 are illustrated below:

A portion of the dielectric film 133 and a portion of the insulating stacked structure 140 can be formed through an etching process to formed a trench 601 in the device region 10D. The trench 601 can extend along the longitudinal direction and penetrate the insulating stacked structure 340. The trench 601 can be formed between the pillar elements 180. A sidewall of the dielectric film 133, a sidewall of the insulating stacked structure 340, and the upper surface 131U of the dielectric layer 131 are exposed by the trench 601.

Then, the insulating films 342 in the insulating stacked structure 340 can be removed through the trench 601 by an etching process to form spaces (not shown) between the insulating layers 341. This etching process only removes the portion of the insulating films 342 located in the device region 10D, but does not remove the portion of the insulating films 342 located in the peripheral region 10P. The retained portion of the insulating films 342 (i.e. the portion of the insulating films 342 located in the peripheral region 10P) can be defined as the insulating films 142.

Then, the conductive layers 172 can be formed in the spaces between the insulating layers 341 through a deposition process. The portion of the insulating layers 341 in the device region 10D can be defined as the insulating layers 171. The portion of the insulating layers 341 in the peripheral region 10P can be defined as the insulating layers 141. The conductive layers 172 and the insulating layers 171 form the stacked structure 170 in the device region 10D. The insulating layers 141 and the insulating films 142 form the insulating stacked structure 140 in the peripheral region 10P. The conductive layers 172 may include conductive materials such as tungsten.

Then, the separation film 192 and the separation element 191 can be formed sequentially in the trench 601 through a deposition process. The separation film 192 may include an insulating material such as oxide. The separation element 191 may include a semiconductor material or metal material; for example, the semiconductor material is doped or undoped polycrystalline silicon. In an embodiment, the separation element 191 includes doped or undoped polycrystalline silicon, and the separation film 192 includes silicon oxide.

Then, the interlayer dielectric film 153 can be formed above the dielectric film 133 through a deposition process. The interlayer dielectric film 153 may include a dielectric material such as oxide. In an embodiment, the interlayer dielectric film 153 includes silicon oxide.

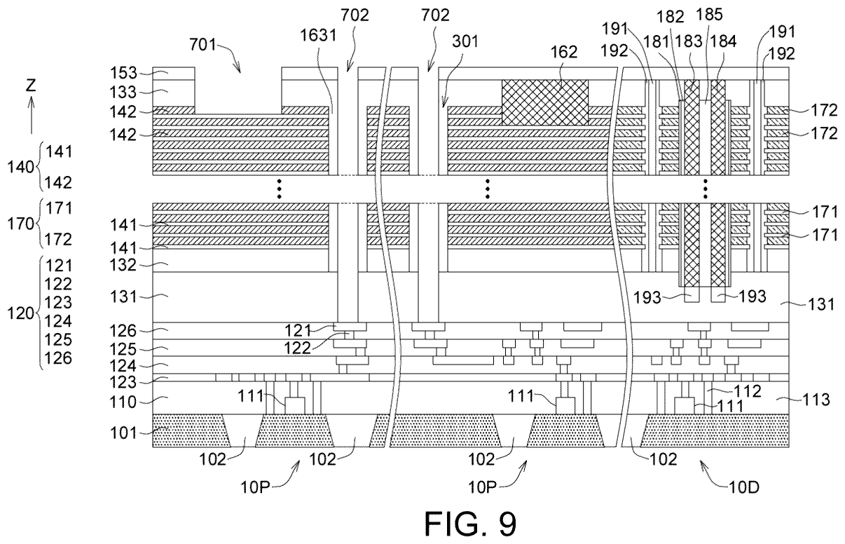

Referring to FIG. 9, FIG. 9 shows a schematic cross-sectional view of the structure at one stage of the method for manufacturing the semiconductor structure. Holes 701 and 702 are formed in the peripheral region 10P. The hole 702 is within the hole 301. The hole 702 can be surrounded by a protection layer 1631 in the hole 301. The upper surface of the conductive element 121 of the lower interconnection structure 120 can be exposed by the hole 702. A sidewall of the dielectric layer 131, a sidewall of the protection layer 1631, a sidewall of the dielectric film 133, and a sidewall of the interlayer dielectric film 153 can be exposed by the hole 702. The hole 701 is in the interlayer dielectric film 153, the dielectric film 133 and the insulating stacked structure 140. A portion of the interlayer dielectric film 153, a portion of the dielectric film 133, a portion of the dielectric material 3330 and a portion of the dielectric layer 131 can be removed through an etching process to form the hole 702. The retained portion of the dielectric material 3330 in the hole 301 is the protection layer 1631. A portion of the interlayer dielectric film 153, a portion of the dielectric film 133 and a portion of the insulating stacked structure 140 can be removed through an etching process to form the hole 701. In an embodiment, the holes 701 and 702 can be formed through the same etching process, the etching process for forming the holes 701 and 702 is a selective etching process, and the etching rate of oxide (e.g. silicon oxide) is higher than the etching rate of nitride (e.g. silicon nitride) in this etching process; since the hole 702 is mainly formed by removing oxide (e.g. the interlayer dielectric film 153, the dielectric film 133, the dielectric material 3330 and the dielectric layer 131), and formation of the hole 701 involves removing nitride (e.g. the insulating film 142), the selective etching process for forming the hole 701 will stop at the first to third insulating films 142 from the top in the insulating stacked structure 140. When the selective etching process for forming the hole 701 stops at the first insulating film 142 from the top in the insulating stacked structure 140, as shown in FIG. 9, the bottom of the hole 701 can be the first insulating film 142, or the bottom of the hole 701 can be the insulating layer 141 below and adjacent to the first insulating film 142 (that is, the etching process removes the first insulating film 142, and shortly afterward, the etching process stops). When the selective etching process for forming the hole 701 stops at the second insulating film 142 from the top in the insulating stacked structure 140, the bottom of the hole 701 can be the second insulating film 142, or the bottom of the hole 701 can be the insulating layer 141 below and adjacent to the second insulating film 142 (that is, the etching process removes the second insulating film 142, and shortly afterward, the etching process stops). When the selective etching process for forming the hole 701 stops at the third insulating film 142 from the top in the insulating stacked structure 140, the bottom of the hole 701 can be the third insulating film 142, or the bottom of the hole 701 can be the insulating layer 141 below and adjacent to the third insulating film 142 (that is, the etching process removes the third insulating film 142, and shortly afterward, the etching process stops).

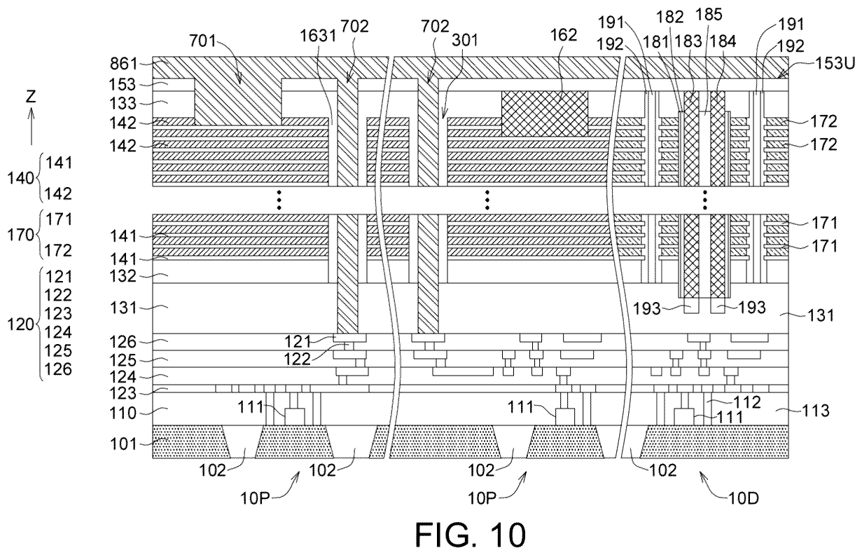

Referring to FIG. 10, FIG. 10 shows a schematic cross-sectional view of the structure at one stage of the method for manufacturing the semiconductor structure. A conductive material 861 is formed. The conductive material 861 can be formed on an upper surface 153U of the interlayer dielectric film 153. The conductive material 861 can extend along the lateral direction and across the device region 10D and the peripheral region 10P. The conductive material 861 can be formed in the holes 701 and 702. The conductive material 861 may be a semiconductor material or metal material; for example, the semiconductor material is doped or undoped polycrystalline silicon; for example, metal material is tungsten. In an embodiment, the conductive material 861 is tungsten.

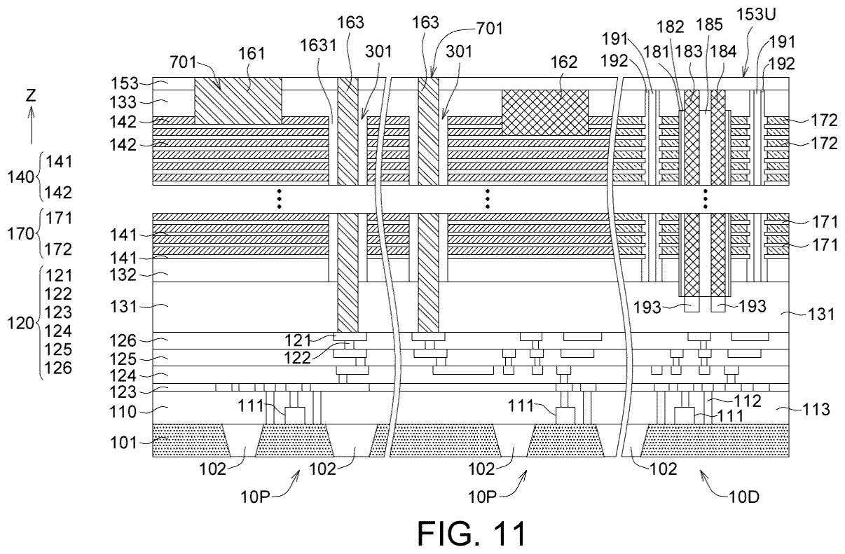

Referring to FIG. 11, FIG. 11 shows a schematic cross-sectional view of the structure at one stage of the method for manufacturing the semiconductor structure. A first resistor element 161 is formed in the peripheral region 10P. A contact element 163 is formed in the peripheral region 10P. A portion of the conductive material 861 on the upper surface 153U of the interlayer dielectric film 153 can be removed through a polishing process, and portions of the conductive material 861 in the holes 701 and 702 are retained. The portion of the conductive material 861 in the hole 701 is the first resistor element 161. The portion of the conductive material 861 in the hole 702 is the contact element 163. Through the selectivity of the etching process and the characteristics of materials, a resistor element with uniform thickness in the longitudinal direction can be formed.

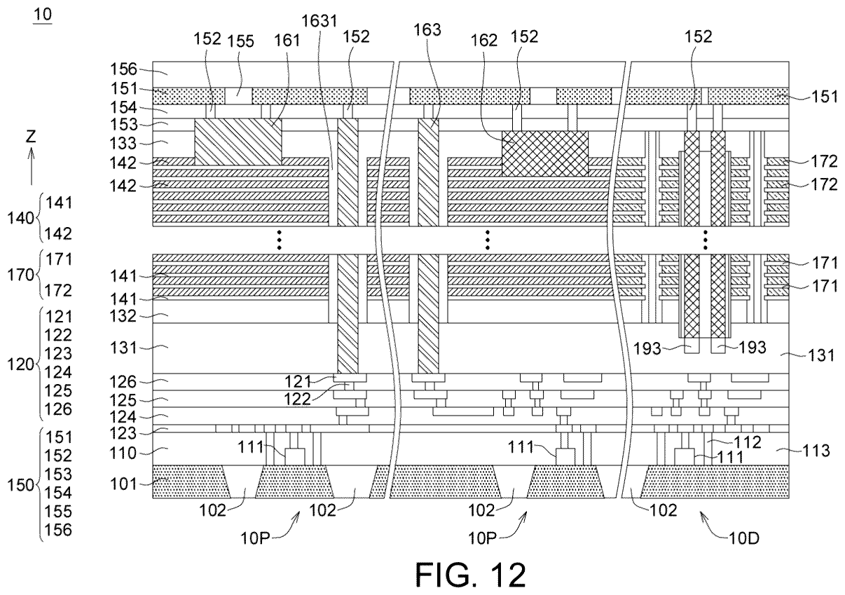

Referring to FIG. 12, FIG. 12 shows a schematic cross-sectional view of the structure at one stage of the method for manufacturing the semiconductor structure. An interlayer dielectric film 154 is formed on the upper surface 153U of the interlayer dielectric film 153. Upper conductive via elements 152 are formed in the interlayer dielectric film 154. An interlayer dielectric film 155 is formed above the interlayer dielectric film 154. Upper conductive elements 151 are formed in the interlayer dielectric film 155. An interlayer dielectric film 156 is formed above the interlayer dielectric film 155. The upper conductive elements 151, the upper conductive via elements 152 and the interlayer dielectric films 153~156 can form an upper interconnection structure 150. The interlayer dielectric films 153~156 can extend along the lateral direction and across the device region 10D and the peripheral region 10P. At least one upper conductive via element 152 can penetrate the interlayer dielectric films 153 and 154 and be electrically connected between the upper conductive element 151 and the second resistor element 162. At least one upper conductive via element 152 can penetrate the interlayer dielectric film 154 and be electrically connected between the upper conductive element 151 and the first resistor element 161. At least one upper conductive via element 152 can penetrate the interlayer dielectric film 154 and be electrically connected between the upper conductive element 151 and the contact element 163. At least one upper conductive via element 152 can penetrate the interlayer dielectric films 153 and 154 and be electrically connected between the upper conductive element 151 and the first conductive pillar 183. At least one upper conductive via element 152 can penetrate the interlayer dielectric films 153 and 154 and be electrically connected between the upper conductive element 151 and the second conductive pillar 184. The upper conductive elements 151 and the upper conductive via elements 152 may includes conductive materials such as tungsten, cobalt, copper, aluminum or silicide. In an embodiment, the upper conductive elements 151 and the upper conductive via elements 152 include tungsten. The interlayer dielectric films 153~156 may include dielectric materials such as oxide. In an embodiment, the interlayer dielectric films 153~156 include silicon oxide.

In an embodiment, through the method schematically illustrated in FIGS. 5 to 12, a semiconductor structure 10 as shown FIG. 1 is provided.

The present disclosure provides a semiconductor structure including a resistor element partially above the insulating stacked structure, and the resistor element has a uniform thickness in the longitudinal direction, which can improve the electrical performance of the semiconductor structure. The present disclosure uses existing manufacturing processes to form the resistor element with uniform thickness without additional manufacturing steps, which is beneficial to cost control and manufacturing process integration. The present disclosure provides a semiconductor structure with a different layout by changing the configuration of the resistor element, thereby improving the overall performance of the semiconductor structure. Moreover, the length and shape of the resistor element of the present disclosure can be easily adjusted to meet various needs.

The present disclosure can form two kinds of resistor elements in the semiconductor structure without increasing the manufacturing process. The two kinds of resistor elements can have different resistance values, so the user can choose which resistor element to use based on needs. For example, for higher resistance value requirements, the second resistor element 162 can be used; for lower resistance value requirements, the first resistor element 161 can be used (the present disclosure is not limited thereto). For example, high resistance value (HRR) can be used for “unselected cells” to ensure stable writing and avoid unselected bit lines from being affected by leakage current. Low resistance value (LRR) can be used for the “selected cell” to ensure reading/writing speed, reduce the generation of RC delay, improve response time, and balance power consumption, speed and stability. That is to say, the resistor element with a high resistance value (HRR) is used to reduce interference, and the resistor element with a low resistance value (LRR) is used to increase the speed. This two kinds of resistor elements have a complementary relationship in the three-dimensional memory device. Specifically, for semiconductor structures including a NOR type memory device, high resistance value (HRR) can be used for unselected word lines (i.e., isolation areas of peripheral word lines) and can be used for isolation between word lines to reduce the influence of adjacent bit lines, thereby improving selectivity and preventing false reads. For a semiconductor structure including a NOR type memory device, low resistance value (LRR) can be used inside the selected word line and bit line to reduce the voltage drop of the bit line, so that the access speed can be improved and the high-performance of the NOR type memory device can be ensured. For semiconductor structures including a NAND type memory device, high resistance values (HRR) can be used for unselected word lines and bit lines (i.e., isolation areas between unselected bit lines and word lines), which can reduce leakage current and prevent adjacent memory cells from being erroneously triggered. For semiconductor structures including a NAND type memory device, high resistance values (HRR) can be used to suppress sneak path current, prevent interference between bit lines, and ensure reading stability. For semiconductor structures including a NAND type memory device, low resistance value (LRR) can be used in selected memory cells (that is, selected bit lines, word lines and control switches) to ensure the low RC delay in the reading/writing process, improve speed and improve efficiency.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a substrate;
an insulating stacked structure on the substrate;
a stacked structure on the substrate and comprising conductive layers and first insulating layers stacked alternately;
a pillar element penetrating the stacked structure and comprising a memory layer and a channel layer, wherein the memory layer surrounds the channel layer;
a first resistor element, wherein a portion of the first resistor element is in the insulating stacked structure, and another portion of the first resistor element is above the insulating stacked structure; and
a dielectric film covering an upper surface of the first resistor element,
wherein the semiconductor structure has a device region and a peripheral region, the insulating stacked structure and the first resistor element are in the peripheral region, and the stacked structure is in the device region.

2. The semiconductor structure according to claim 1, further comprising a device layer and a contact element, wherein the device layer is between the substrate and the insulating stacked structure, the device layer includes one or more transistors, the contact element penetrates the insulating stacked structure, and the first resistor element is electrically connected to the one or more transistors through the contact element.

3. The semiconductor structure according to claim 2, further comprising an upper interconnection structure and a lower interconnection structure, wherein the upper interconnection structure is above the insulating stacked structure, the lower interconnection structure is between the device layer and the insulating stacked structure, and the first resistor element is electrically connected to the one or more transistors through the upper interconnection structure, the contact element and the lower interconnection structure.

4. The semiconductor structure according to claim 2, further comprising a second resistor element, wherein a portion of the second resistor element is in the insulating stacked structure, another portion of the second resistor element is above the insulating stacked structure, the insulating stacked structure is disposed on the substrate along a longitudinal direction, and the first resistor element is on one side of the contact element.

5. The semiconductor structure according to claim 4, wherein the first resistor element and the second resistor element comprise different materials, and a resistance value of the first resistive element is greater than a resistance value of the second resistive element.

6. The semiconductor structure according to claim 5, wherein the first resistor element comprises tungsten, and the second resistor element comprise polycrystalline silicon.

7. The semiconductor structure according to claim 1, wherein the insulating stacked structure comprises second insulating layers and insulating films stacked alternately along a longitudinal direction, the second insulating layers and the insulating films comprise different materials, the insulating films comprise nitride, the first resistor element overlaps N insulating films of the insulating films in a lateral direction, and 1≤N≤3.

8. The semiconductor structure according to claim 1, further comprising a second resistor element, wherein a portion of the second resistor element is in the insulating stacked structure, another portion of the second resistor element is above the insulating stacked structure, the insulating stacked structure comprises insulating layers and insulating films stacked alternately along a longitudinal direction, the insulating films comprise nitride, the first resistor element overlaps N insulating films of the insulating films in a lateral direction, 1≤N≤3, the second resistor element overlaps M insulating films of the insulating films in the lateral direction, 2≤M≤3.

9. The semiconductor structure according to claim 1, further comprising contact elements separated from each and penetrating the insulating stacked structure, a width of the first resistor element is smaller than or equal to a width of one of the contact elements.

10. The semiconductor structure according to claim 9, further comprising a separation element penetrating the stacked structure and between the pillar element and the insulating stacked structure.

11. The semiconductor structure according to claim 9, further comprising a device layer and a lower interconnection structure, wherein the device layer is between the substrate and the insulating stacked structure, the device layer includes one or more transistors, the lower interconnection structure is between the insulating stacked structure and the device layer, the contact elements are electrically connected to the one or more transistors through the lower interconnection structure.

12. The semiconductor structure according to claim 9, further comprising a second resistor element, wherein a portion of the second resistor element is in the insulating stacked structure, another portion of the second resistor element is above the insulating stacked structure, and the first resistor element and the second resistor element are disposed between the contact elements.

13. The semiconductor structure according to claim 9, wherein at least one contact element of the contact elements is between the first resistor element and the stacked structure.

14. The semiconductor structure according to claim 1, further comprising contact elements separated from each other, extend along a longitudinal direction and penetrating the insulating stacked structure, wherein the first resistor element extends through contact elements along a lateral direction.

15. The semiconductor structure according to claim 1, wherein the insulating stacked structure comprises a first insulating film, a second insulating film, a third insulating film and a fourth insulating film arranged sequentially from top to bottom and separated from each other, the first insulating film, the second insulating film, the third insulating film and the fourth insulating film comprise nitride, the first insulating film is located on top of the insulating stacked structure, and a lower surface of the first resistor element is higher than an upper surface of the fourth insulating film.

16. The semiconductor structure according to claim 15, wherein the lower surface of the first resistor element is in the first insulating film or at the same height as a lower surface of the first insulating film.

17. The semiconductor structure according to claim 15, wherein the lower surface of the first resistor element is in the second insulating film or at the same height as a lower surface of the second insulating film.

18. The semiconductor structure according to claim 1, wherein the pillar element comprises a first conductive pillar, a second conductive pillar and an insulating pillar, the channel layer surrounds the first conductive pillar and the second conductive pillar, and the insulating pillar is between the first conductive pillar and the second conductive pillar.

19. The semiconductor structure according to claim 18, further comprising contact elements separated from each other and penetrating the insulating stacked structure, wherein the first resistor element is in a space between the contact elements.

20. The semiconductor structure according to claim 19, further comprising protection layers on sidewalls of the contact elements.
